(19) United States
(12) Patent Application Publication
(10) Pub. No.: US 2024/0172412 A1
(43) Pub. Date: May 23, 2024

(54) Memory Circuitry And Methods Used In Forming Memory Circuitry

(71) Applicant: Micron Technology, Inc., Boise, ID (US)

(72) Inventors: Li Wei Fang, Taichung City (TW); Vivek Yadav, Boise, ID (US); Jordan D. Greenlee, Nampa, ID (US); Silvia Borsari, Boise, ID (US)

(73) Assignee: Micron Technology, Inc., Boise, ID (US)

(21) Appl. No.: 18/241,035

(22) Filed: Aug. 31, 2023

Related U.S. Application Data
(60) Provisional application No. 63/427,324, filed on Nov. 22, 2022.

(51) Int. Cl. H10B 12/00

(52) U.S. Cl. CPC H10B 12/053; H10B 12/315; H10B 12/34

(57) ABSTRACT

A method used in forming memory circuitry comprises forming transistors individually comprising one source/drain region and another source/drain region. A channel region is between the one and the another source/drain regions. A conductive gate is operatively proximate the channel region. Openings are formed through insulative material that is directly above the transistors and into the another source/drain regions. Individual of the openings are directly above individual of the another source/drain regions. A laterally-outer insulator material is formed in the individual openings within and below the insulative material. A laterally-inner insulator material is formed in the individual openings within and below the insulative material laterally-over the laterally-outer insulator material. The laterally-outer insulator material and the laterally-inner insulator material are directly against one another and have an interface there-between. The laterally-inner insulator material that is in the individual openings below the insulative material is removed. After such removing, conductor material is formed in the individual openings that is electrically coupled to one of the individual another source/drain regions. The laterally-outer insulator material, the laterally-inner insulator material, and the conductor material that are in the individual openings comprise individual conductive-via constructions. Digitlines are formed directly above the insulative material and that are individually electrically coupled to the conductor material of one of the individual conductive-via constructions. Storage elements are formed that are individually electrically coupled to individual of the one source/drain regions. Structure is disclosed.

### TECHNICAL FIELD

Embodiments disclosed herein pertain to memory circuitry and to methods used in forming memory circuitry.

### BACKGROUND

Memory is one type of integrated circuitry and is used in computer systems for storing data. Memory may be fabricated in one or more arrays of individual memory cells. Memory cells may be written to, or read from, using digitlines (which may also be referred to as bitlines, data lines, or sense lines) and access lines (which may also be referred to as wordlines). The digitlines may conductively interconnect memory cells along columns of the array, and the access lines may conductively interconnect memory cells along rows of the array. Each memory cell may be uniquely addressed through the combination of a digitline and an access line.

Memory cells may be volatile, semi-volatile, or non-volatile. Non-volatile memory cells can store data for extended periods of time in the absence of power. Non-volatile memory is conventionally specified to be memory having a retention time of at least about 10 years. Volatile memory dissipates and is therefore refreshed/rewritten to maintain data storage. Volatile memory may have a retention time of milliseconds or less. Regardless, memory cells are configured to retain or store memory in at least two different selectable states. In a binary system, the states are considered as either a “0” or a “1”. In other systems, at least some individual memory cells may be configured to store more than two levels or states of information.

A capacitor is one type of electronic component that may be used in a memory cell. A capacitor has two electrical conductors separated by electrically insulating material. Energy as an electric field may be electrostatically stored within such material. Depending on composition of the insulator material, that stored field will be volatile or non-volatile. For example, a capacitor insulator material including only SiO₂ will be volatile. One type of non-volatile capacitor is a ferroelectric capacitor which has ferroelectric material as at least part of the insulating material. Ferroelectric materials are characterized by having two stable polarized states and thereby can comprise programmable material of a capacitor and/or memory cell. The polarization state of the ferroelectric material can be changed by application of suitable programming voltages and remains after removal of the programming voltage (at least for a time). Each polarization state has a different charge-stored capacitance from the other, and which ideally can be used to write (i.e., store) and read a memory state without reversing the polarization state until such is desired to be reversed. Less desirable, in some memory having ferroelectric capacitors the act of reading the memory state can reverse the polarization. Accordingly, upon determining the polarization state, a re-write of the memory cell is conducted to put the memory cell into the pre-read state immediately after its determination. Regardless, a memory cell incorporating a ferroelectric capacitor ideally is non-volatile due to the bi-stable characteristics of the ferroelectric material that forms a part of the capacitor. Other programmable materials may be used as a capacitor insulator to render capacitors non-volatile.

A field effect transistor is another type of electronic component that may be used in a memory cell. These transistors comprise a pair of conductive source/drain regions having a semiconductive channel region there-between. A conductive gate is adjacent the channel region and separated there-from by a thin gate insulator. Application of a suitable voltage to the gate allows current to flow from one of the source/drain regions to the other through the channel region. When the voltage is removed from the gate, current is largely prevented from flowing through the channel region. Field effect transistors may also include additional structure, for example a reversibly programmable charge-storage region as part of the gate construction between the gate insulator and the conductive gate. Regardless, the gate insulator may be programmable, for example being ferroelectric.

### BRIEF DESCRIPTION OF THE DRAWINGS

FIGS. 1-5 are diagrammatic cross-sectional views of a portion of a DRAM construction in fabrication in accordance with some embodiments of the invention.

FIGS. 6-33 are diagrammatic sequential sectional views of the construction of FIGS. 1-5 in subsequent processing in accordance with some embodiments of the invention.

### DETAILED DESCRIPTION OF EXAMPLE EMBODIMENTS

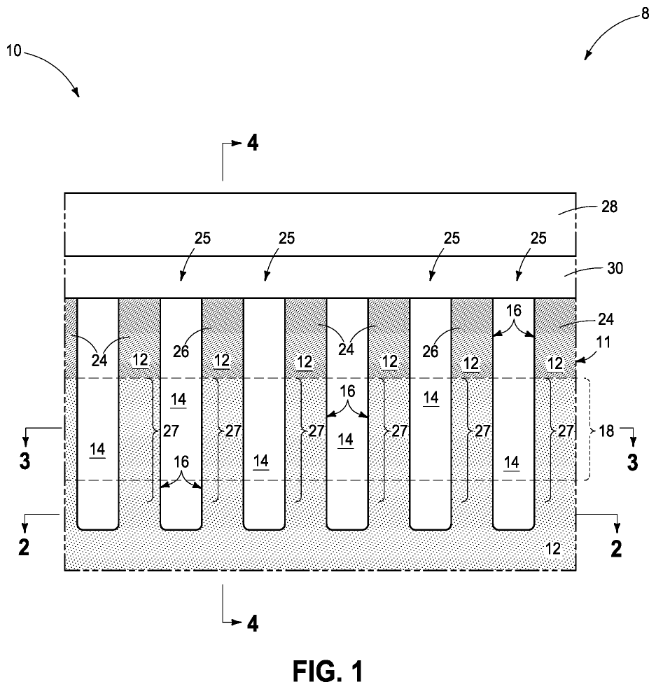

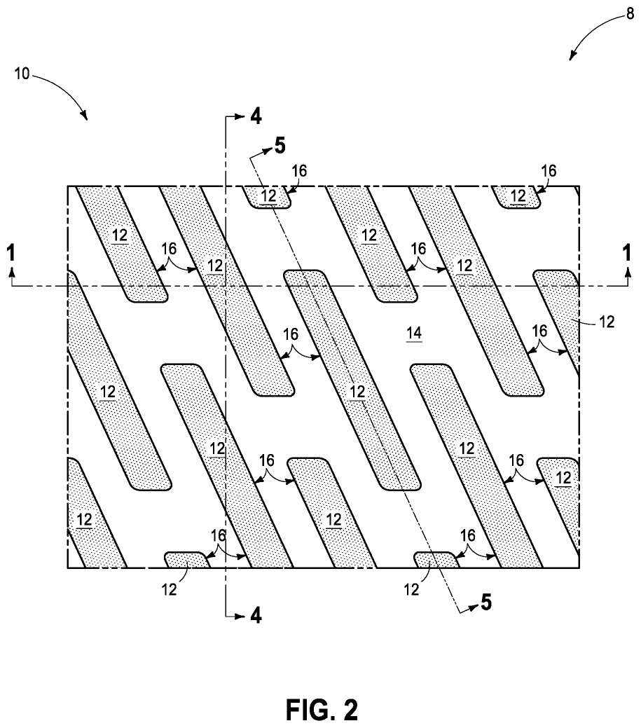

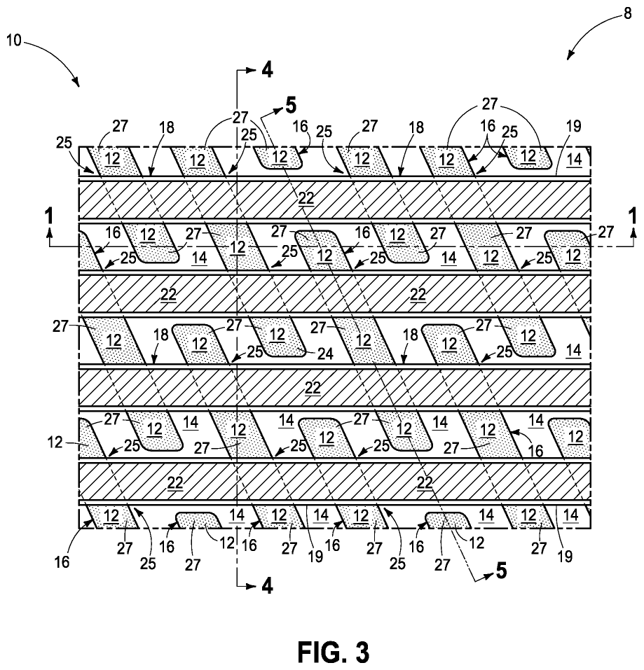

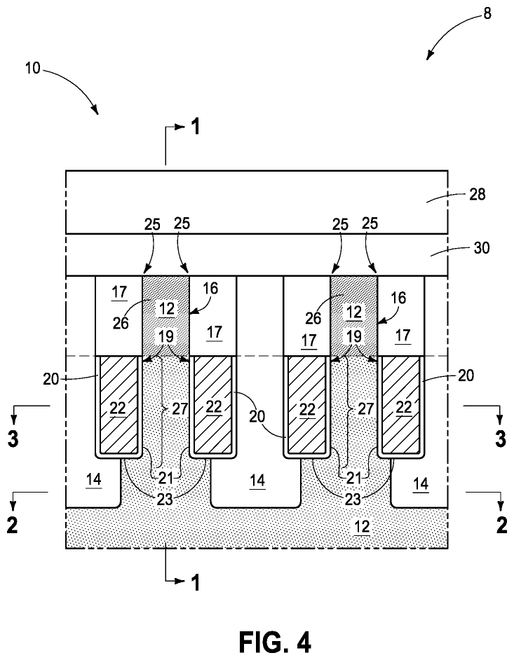

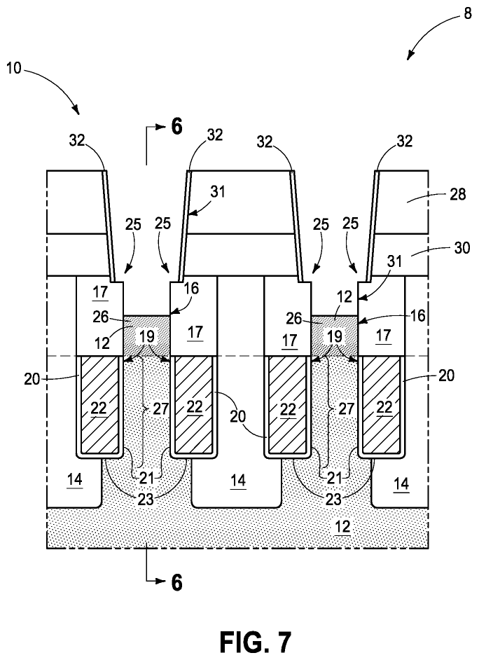

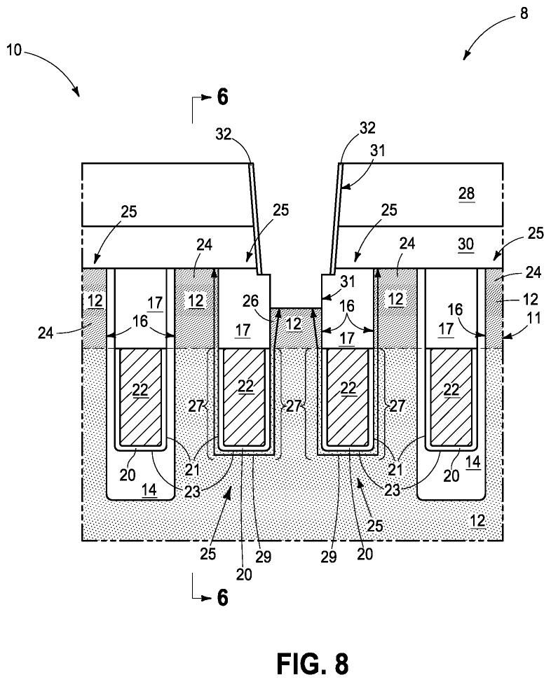

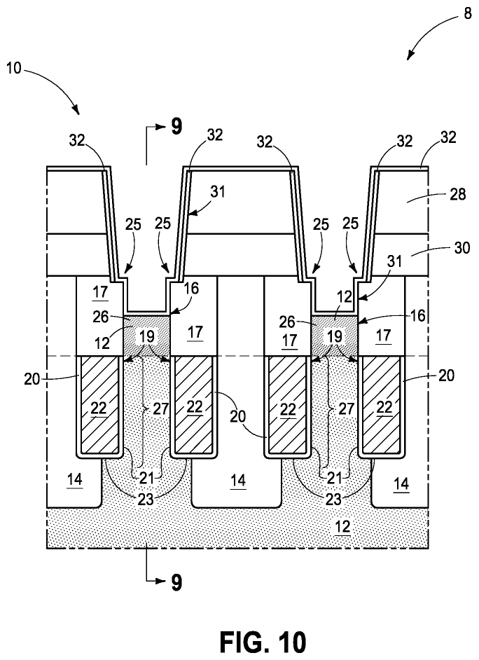

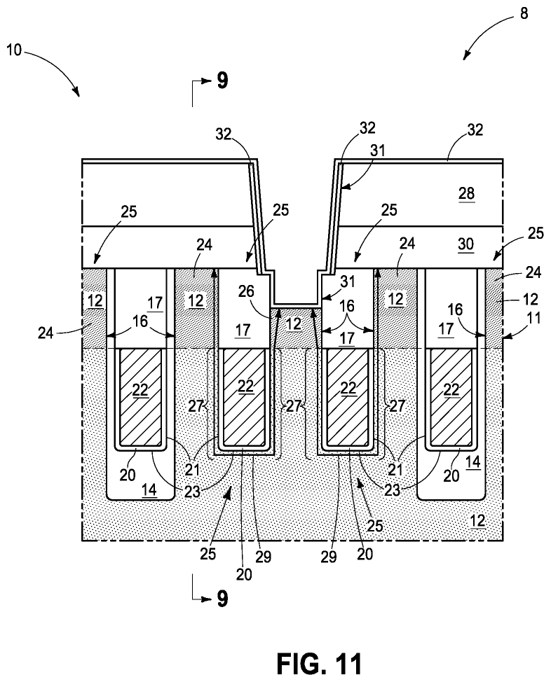

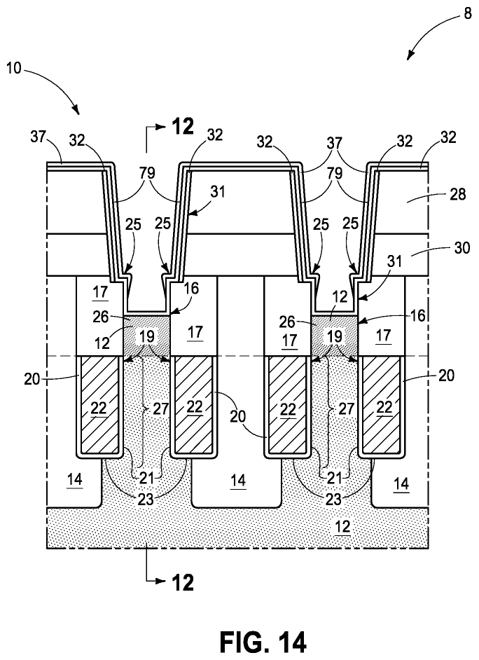

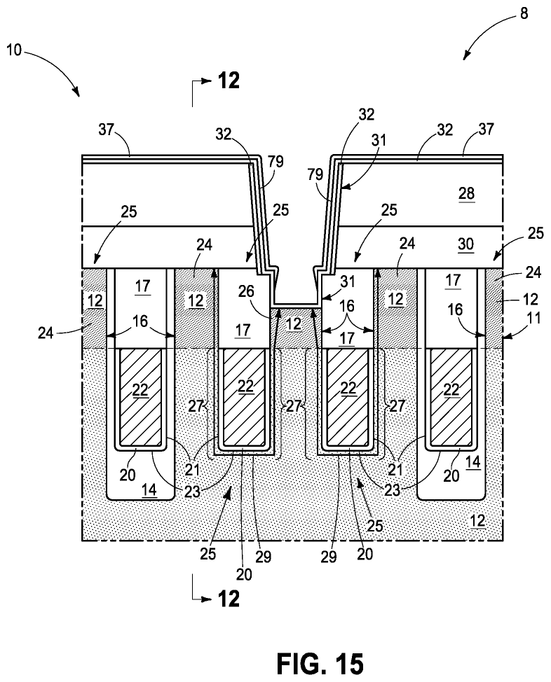

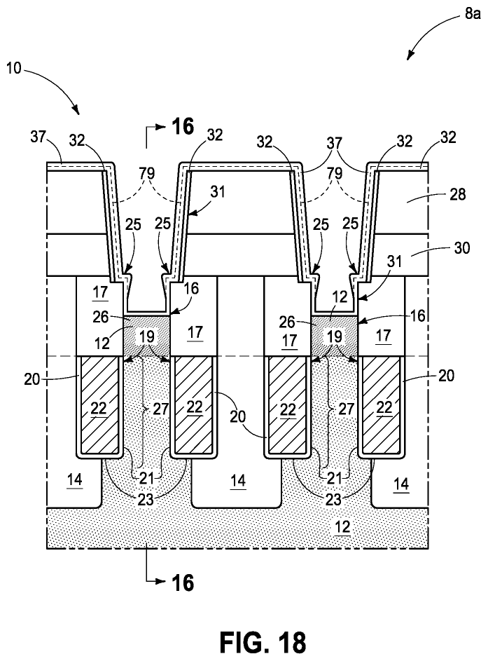

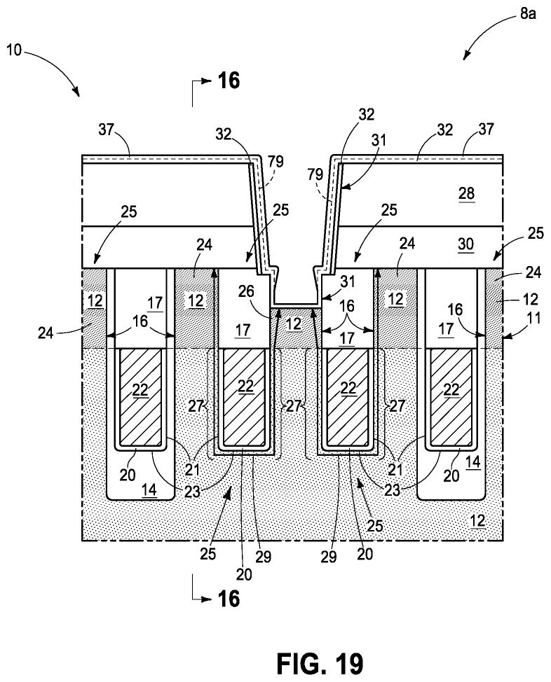

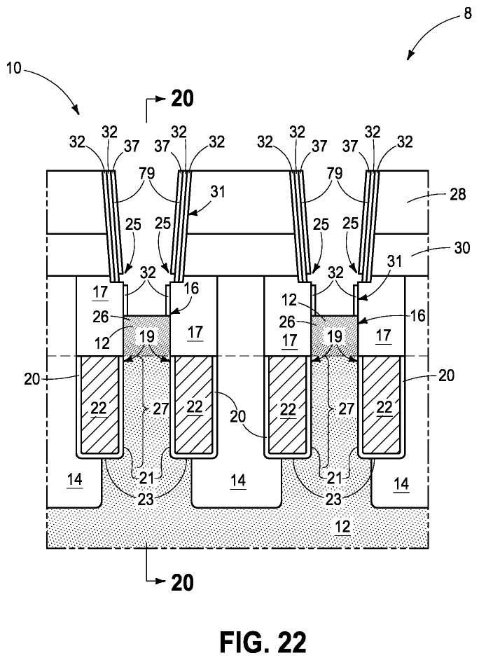

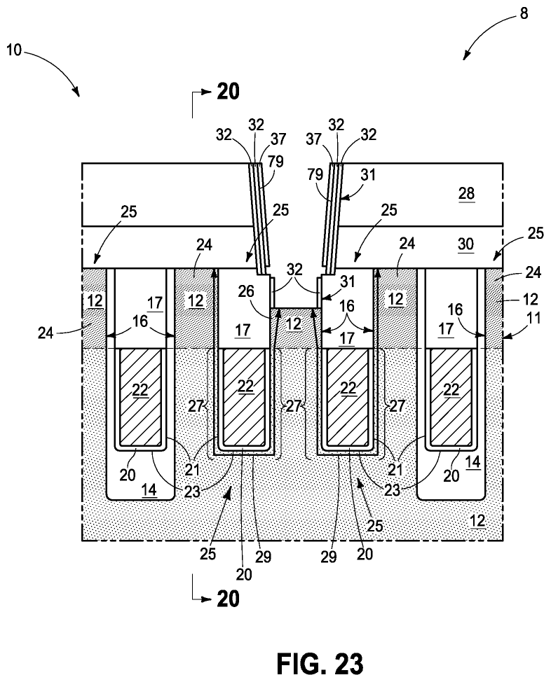

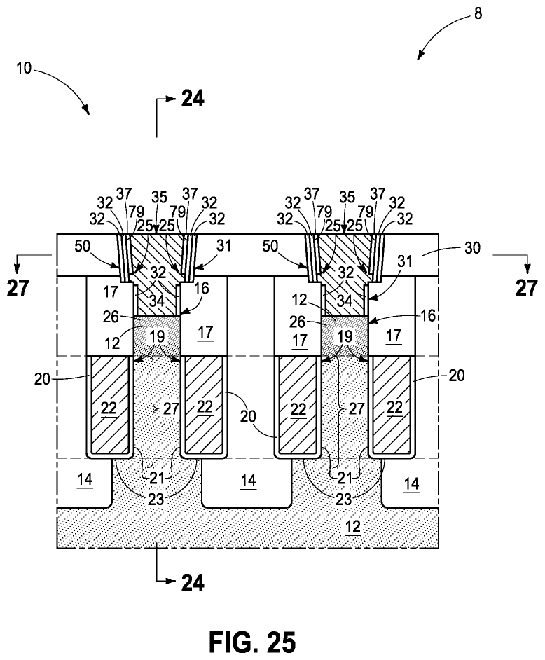

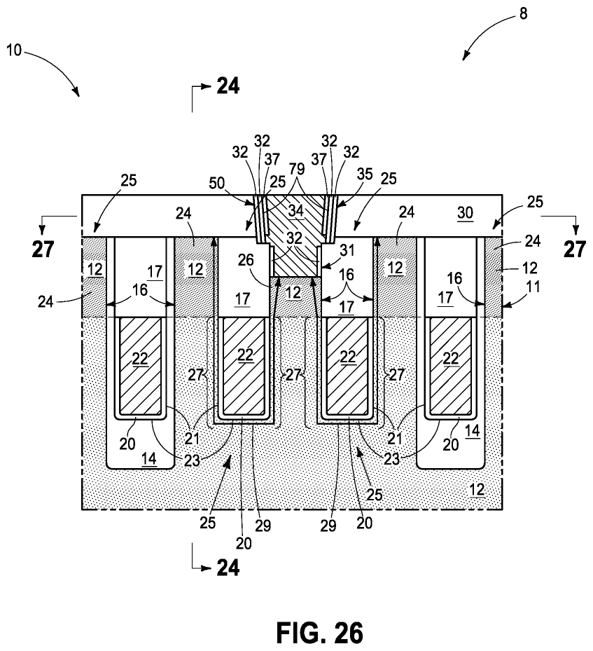

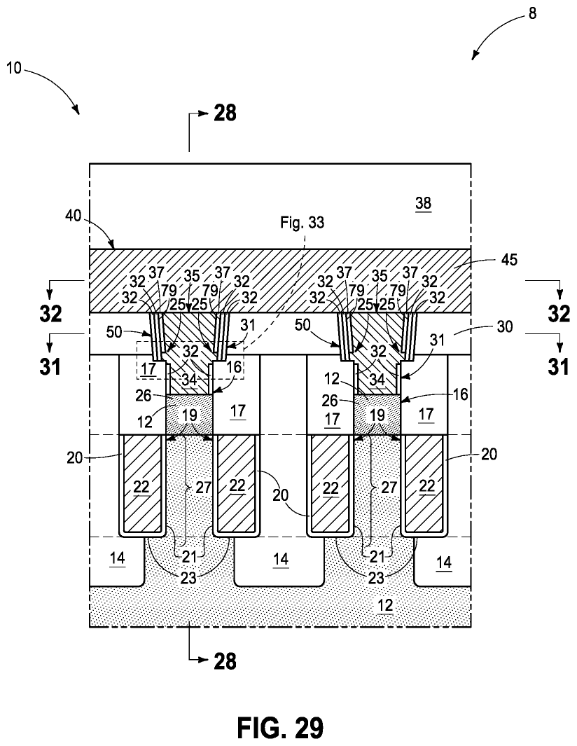

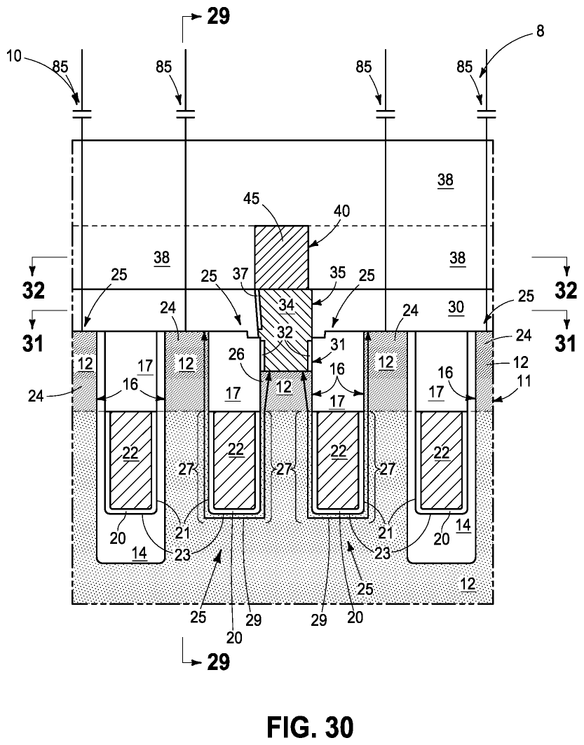

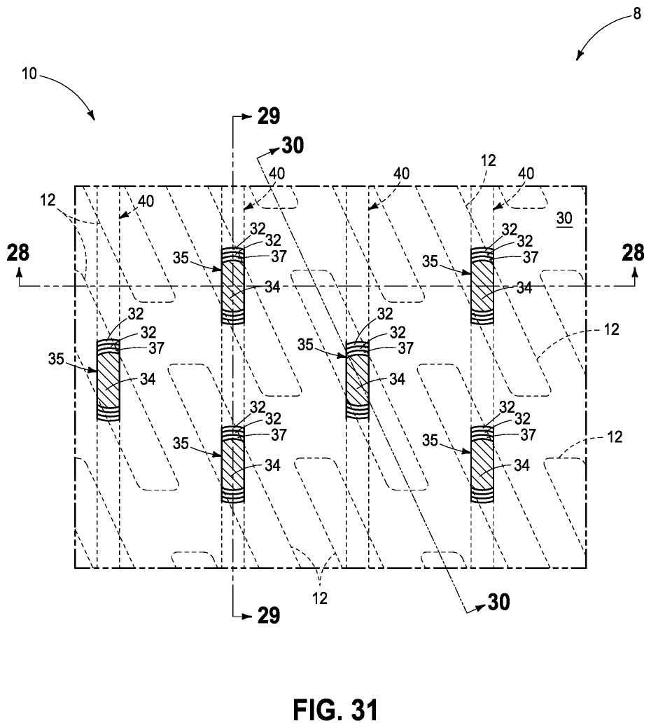

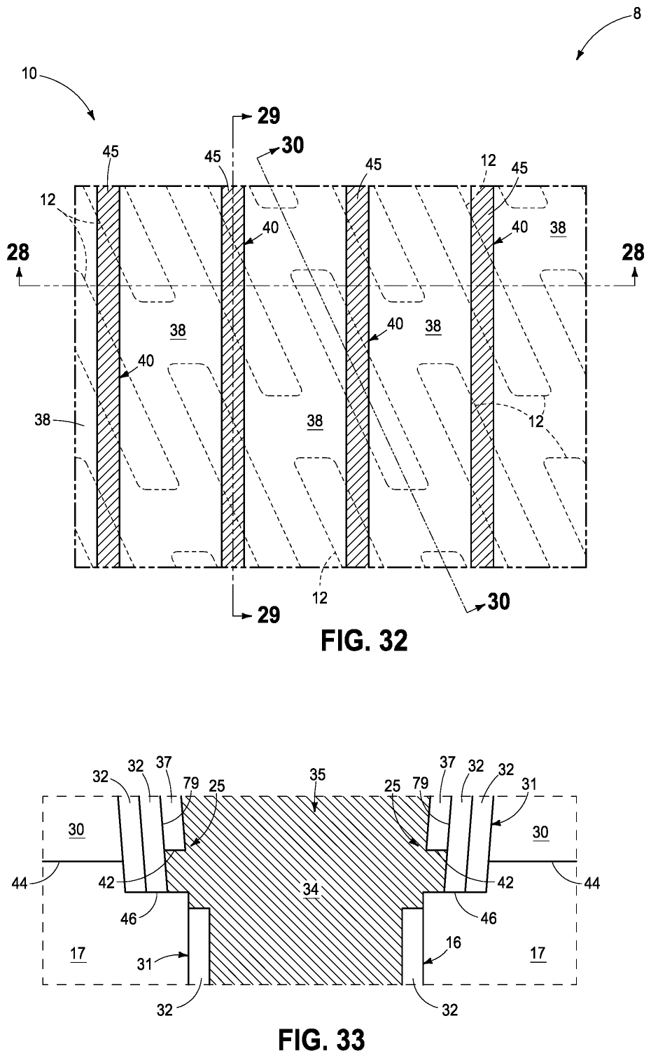

Embodiments of the invention encompass memory circuitry, such as DRAM, and methods used in forming memory circuitry, such as a DRAM. First example method embodiments are described with reference to FIGS. 1-32.

Referring to FIGS. 1-5, an example fragment of a substrate construction 8 comprising an array or array area 10 has been fabricated relative to a base substrate 11. Substrate 11 may comprise any one or more of conductive/conductor/conducting, semiconductive/semiconductor/semiconducting, and insulative/insulator/insulating (i.e., electrically herein) materials. Materials may be aside, elevationally inward, or elevationally outward of the FIGS. 1-5-depicted materials. For example, other partially or wholly fabricated components of integrated circuitry may be provided somewhere above, about, or within base substrate 11. Control and/or other peripheral circuitry for operating components within a memory array may also be fabricated and may or may not be wholly or partially within a memory array or sub-array. Further, multiple sub-arrays may also be fabricated and operated independently, in tandem, or otherwise relative one another. As used in this document, a “sub-array” may also be considered as an array.

Base substrate 11 comprises semiconductive material 12 (e.g., appropriately and variously doped monocrystalline and/or polycrystalline silicon, Ge, SiGe, GaAs, and/or other existing or future-developed semiconductive material), trench isolation regions 14 (e.g., silicon nitride atop silicon dioxide), and active area regions 16 comprising suitably and variously-doped semiconductive material 12. Construction 8 comprises transistors 25 individually comprising one source/drain region 24 and another source/drain region 26, a channel region 27 between the one and the another source/drain regions, and a conductive gate 22 (e.g., conductively-doped semiconductor material and/or metal material, including for example elemental W, Ru, and/or Mo) operatively proximate channel region 27 (e.g., a gate dielectric 20 being between the conductive gate 22 and channel region 27, for example silicon dioxide and/or silicon nitride). Transistors 25 are shown as being recessed access devices, with example construction 8 showing such recessed access devices grouped in individual pairs of such devices. Individual recessed access devices/transistors 25 include a buried access line construction 18, for example that is within a trench 19 in semiconductive material 12. Constructions 18 comprise conductive gate 22 (e.g., conductively-doped semiconductor material and/or metal material). Gate dielectric 20 is along sidewalls 21 and a base 23 of individual trenches 19 between conductive gate 22 and semiconductive material 12. Insulator material 17 (e.g., silicon dioxide and/or silicon nitride) is within trenches 19 above materials 20 and 22. One source/drain region 24 and another source/drain region 26 are in upper portions of semiconductive material 12 on opposing sides of individual trenches 19 (e.g., regions 24, 26 being laterally-outward of and higher than access line constructions 18). Each of source/drain regions 24, 26 has at least a part thereof having a conductivity-increasing dopant therein that is of maximum concentration of such conductivity-increasing dopant within the respective source/drain region 24, 26, for example to render such part to be conductive (e.g., having a maximum dopant concentration of at least 10¹⁹ atoms/cm³). Accordingly, all or only a part of each source/drain region 24, 26 may have such maximum concentration of conductivity-increasing dopant. Source/drain regions 24 and/or 26 may include other doped regions (not shown), for example halo regions, LDD regions, etc.

In the example embodiment, one of the source/drain regions (e.g., another source/drain region 26) of the pair of source/drain regions in individual of the pairs of transistors 25 is laterally between conductive gates 22 and is shared by the pair of devices 25. Others of the source/drain regions (e.g., one source/drain region 24) of the pair of source/drain regions are not shared by the pair of transistors 25. Thus, in the example embodiment, each active area region 16 comprises two transistors 25 (e.g., one pair of transistors 25), with each sharing a central source/drain region 26.

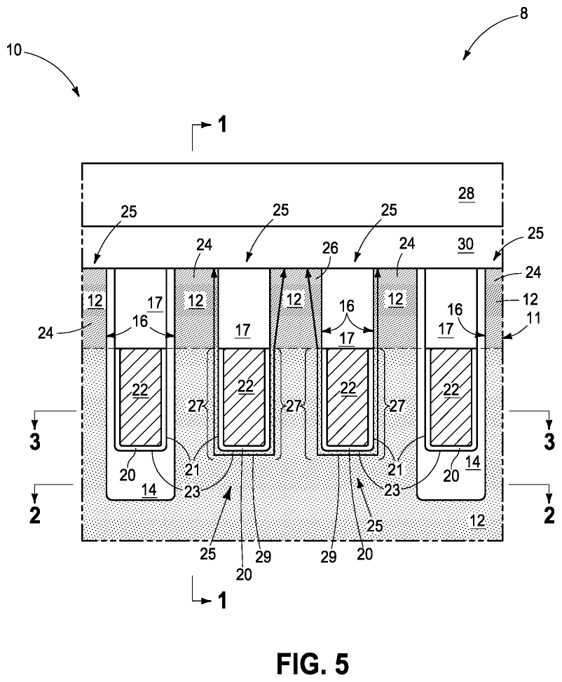

Example channel region 27 is in semiconductive material 12 below pair of source/drain regions 24, 26 along trench sidewalls 21 and around trench base 23. Channel region 27 may be undoped or may be suitably doped with a conductivity-increasing dopant likely of the opposite conductivity-type of the dopant in source/drain regions 24, 26. When suitable voltage is applied to gate material 22 of an access line construction 18, a conductive channel forms (e.g., along a channel current-flow line/path 29 [FIG. 5]) within channel region 27 proximate gate insulator 20 such that current is capable of flowing between a pair of source/drain regions 24 and 26 under the access line construction 18 within an individual active area region 16. Stippling is diagrammatically shown to indicate primary conductivity-modifying dopant concentration (regardless of type), with denser stippling indicating greater dopant concentration and lighter stippling indicating lower dopant concentration. Conductivity-modifying dopant may be, and would likely be, in other portions of material 12 as shown. Only two different stippling densities are shown in material 12 for convenience, and additional dopant concentrations may be used, and constant dopant concentration is not required in any region.

In one embodiment, insulative material 30 (e.g., silicon nitride atop silicon dioxide) is directly above transistors 25. Sacrificial hard-masking material 28 (e.g., silicon dioxide) may be atop insulative material 30.

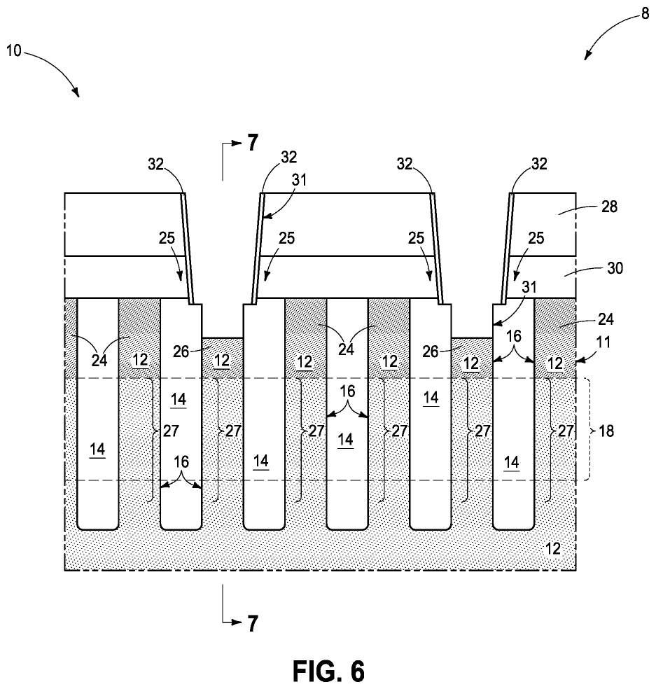

Referring to FIGS. 6-8 (following from FIGS. 1, 4, and 5, respectively), openings 31 have been formed through insulative material 30 (and hard-masking material 28 when present) and that are individually directly above individual another source/drain regions 26. Laterally-outer insulator material 32 (e.g., silicon dioxide) has been formed in individual openings 31, followed by punch-etching thereof to substantially remove such from being over horizontal surfaces and expose material of another source/drain regions 26. Example further etching has thereafter been conducted to extend openings 31 into another source/drain regions 26 as shown. Lateral thickness of laterally-outer insulator material 32 may be reduced in the punch-etching and/or in the subsequent etching into another source/drain region 26 during such etching (as shown).

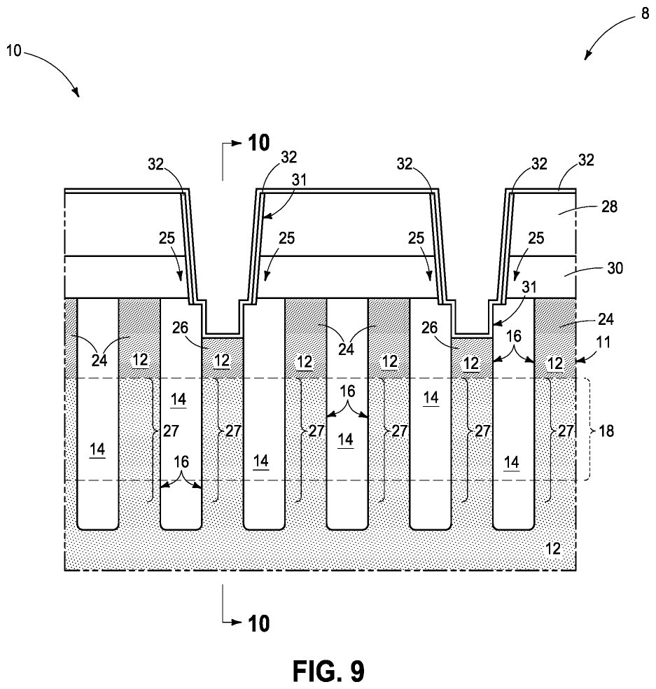

Referring to FIGS. 9-11, additional laterally-outer insulator material 32 has been formed in individual openings 31 within and below insulative material 30. Such is but one example embodiment wherein the forming of laterally-outer insulator material 32 occurs in two (at least) time-spaced deposition steps. The example first and second-deposited materials of laterally-outer insulator material 32 may be of the same composition or of different compositions relative one another.

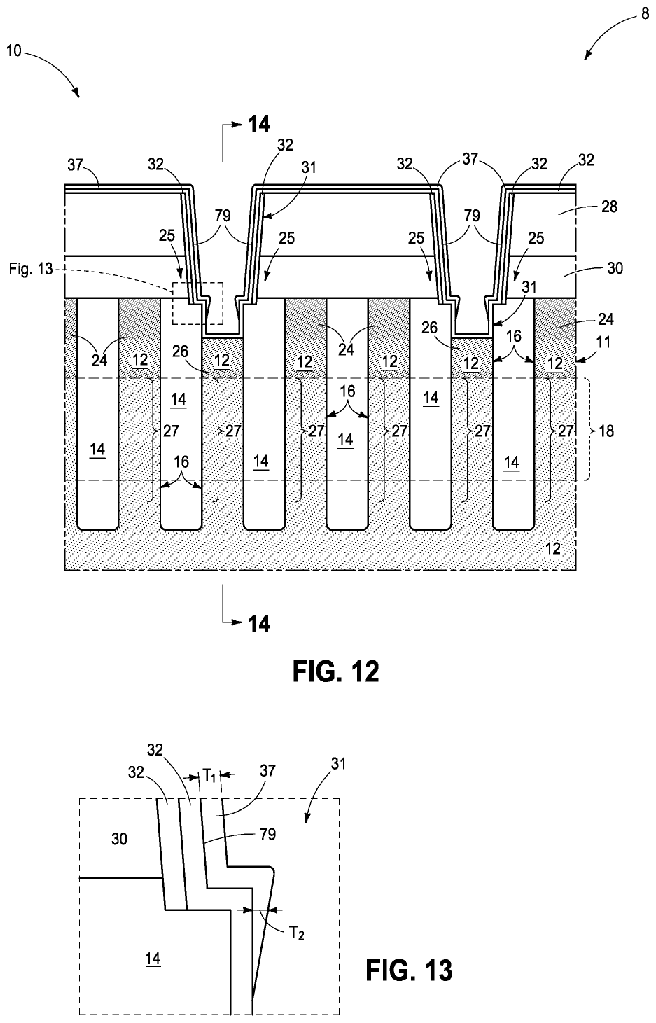

Referring to FIGS. 12-15, a laterally-inner insulator material 37 has been formed in individual openings 31 within and below insulative material 30 laterally-over laterally-outer insulator material 32, with such having an interface 79 there-between. Materials 32 and 37 may of the same composition relative one another at interface 79 or may be of different compositions relative one another at interface 79. In one embodiment and as shown, the forming of laterally-inner insulator material 37 forms such to be laterally-thicker (on average; e.g., T₁ in FIG. 13) in openings 31 within insulative material 30 than in openings 31 below insulative material 30 (T₂). Such may inherently occur as an artifact of manufacture or purposefully by modifying one or more of precursor flow(s), temperature, and pressure as will be recognized by people of skill in the art.

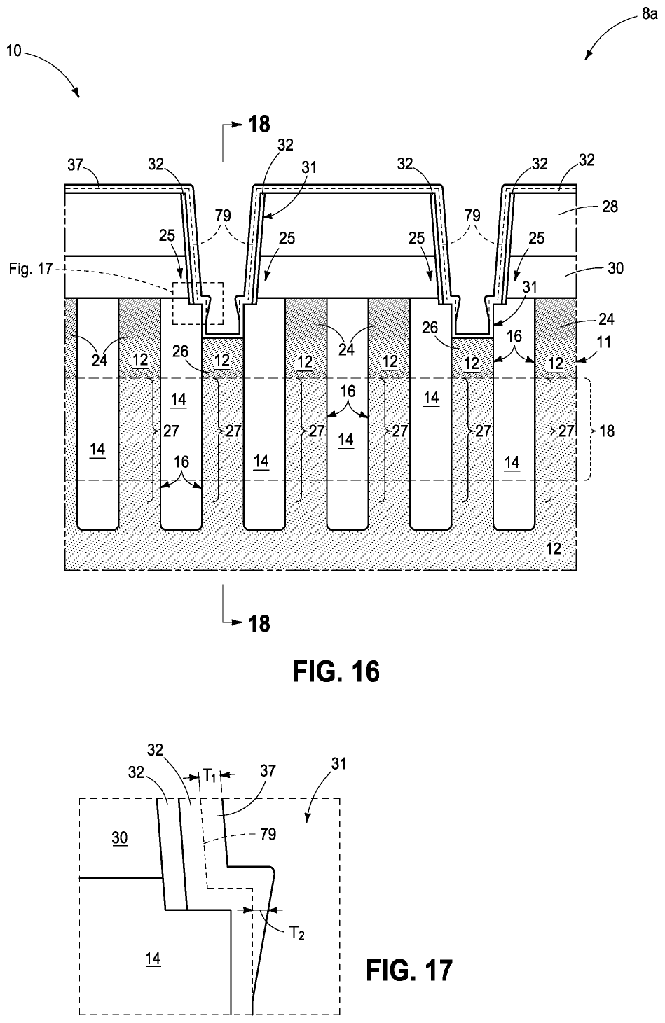

FIGS. 12-15 are intended to show an example where laterally-outer insulator material 32 and laterally-inner insulator material 37 are of different compositions relative one another by a solid separating line/interface 79 between such materials. FIGS. 16-19 are intended to show an example where laterally-outer insulator material 32 and laterally-inner insulator material 37 are of the same composition relative one another by a dashed-line interface 79 being there-between in a construction 8a. Like numerals from the above-described embodiments have been used where appropriate, with some construction differences being indicated with a suffix “a” or with different numerals. Any other attribute(s) or aspect(s) as shown and/or described herein with respect to other embodiments may be used.

Interface 79 may be continuous or interface 79 may be discontinuous at some place(s) there-along. Interface 79 will be continuous when laterally-outer insulator material 32 and laterally-inner insulator material 37 are of different compositions relative one another. Interface 79 may or may not be continuous when laterally-outer insulator material 32 and laterally-inner insulator material 37 are of the same composition relative one another. For example, separate-in-time formed laterally-outer insulator material 32 and laterally-inner insulator material 37 if of the same composition relative one another may nevertheless have a perceptible interface in a finished construction. Some of that interface may effectively disappear (i.e., not be perceptible) and some may remain perceptible whereby that interface is discontinuous in one or more locations longitudinally-there-along (e.g., as may occur by welding of the same-composition materials together due to subsequent heating during manufacture).

In one embodiment, laterally-inner insulator material 37 comprises a nitride, for example at least one of boron nitride, silicon nitride, silicon oxynitride, and aluminum-poor aluminum nitride (“poor” meaning stoichiometrically such that the aluminum nitride is insulative as opposed to semiconductive). Such nitride may be doped with other atoms, for example, at least one of boron, phosphorus, and carbon. In one embodiment, laterally-inner insulator material 37 comprises an oxide, for example comprising at least one of silicon dioxide, germanium oxide, and insulative metal oxide. In one such embodiment where comprising an insulative metal oxide, such comprises multiple different metals. Regardless, the oxide may be doped with additional atoms, for example at least one of boron, phosphorus, and carbon.

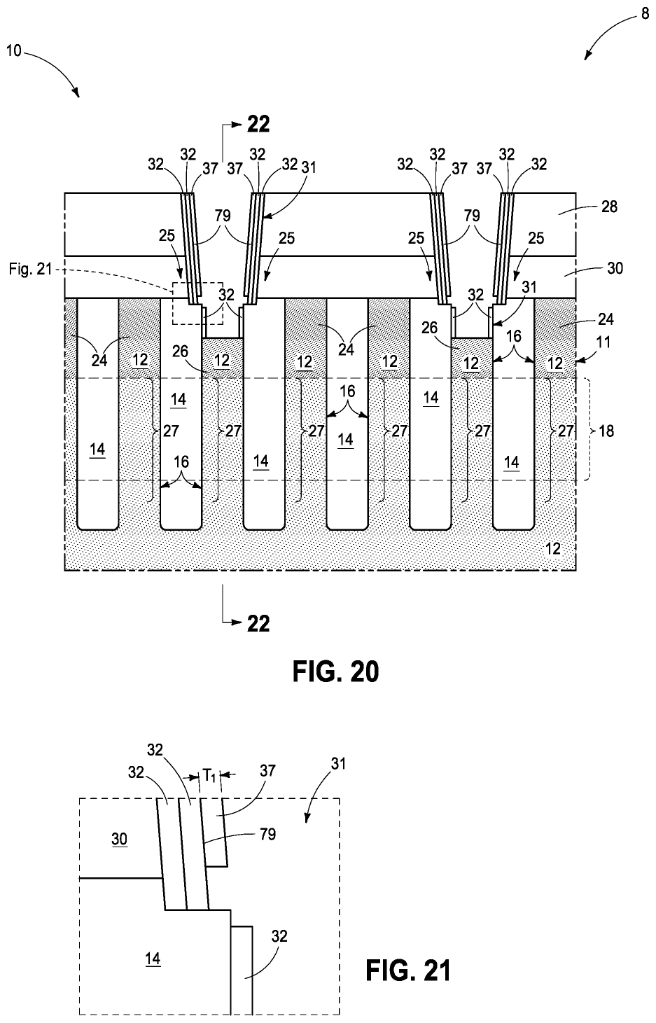

Referring to FIGS. 20-23, and in one embodiment, laterally-inner insulator material 37 that is in individual openings 31 below insulative material 30 has been removed, ideally and in one embodiment with all such material 37 that is below insulative material 30 being removed (e.g., by wet or dry etching that may reduce lateral thickness of laterally-inner insulator material 37 above insulative material 30). Some of laterally-outer insulator material 32 may be removed in the process as shown, for example whereby such material is not continuous (in vertical cross-section) along sidewalls of openings 31.

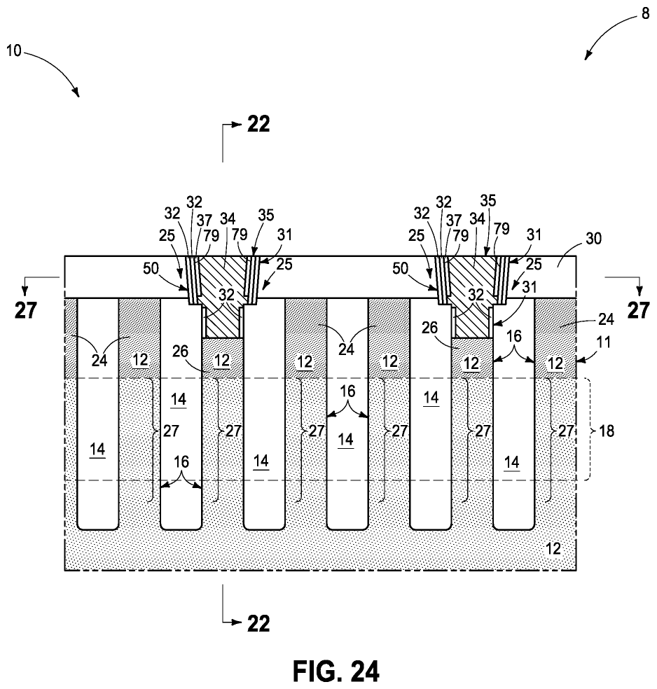

Referring to FIGS. 24-27, conductor material 34 (e.g., at least one of conductively-doped semiconductive material and metal material) has been formed in individual openings 31 and is electrically coupled (e.g., ideally directly electrically coupled) to one of the individual another source/drain regions 26. FIGS. 24-26 show planarizing/etch-back of materials that are above insulative material 30 at least to the top of insulative material 30. Thereby, conductive-via constructions 35 have been formed in individual openings 31 and that individually comprise an insulator lining 50 laterally-outward of conductor material 34, with example insulator lining 50 comprising laterally-outer insulator material 32 and laterally-inner insulator material 37.

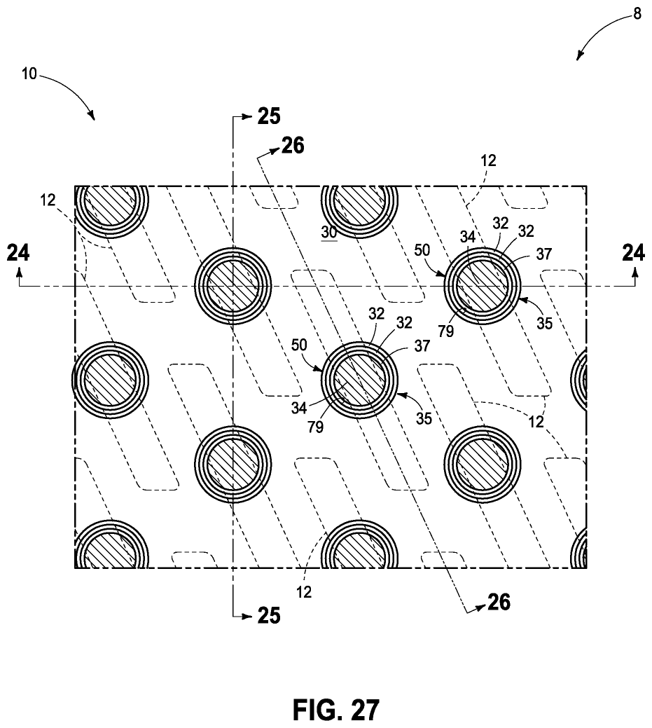

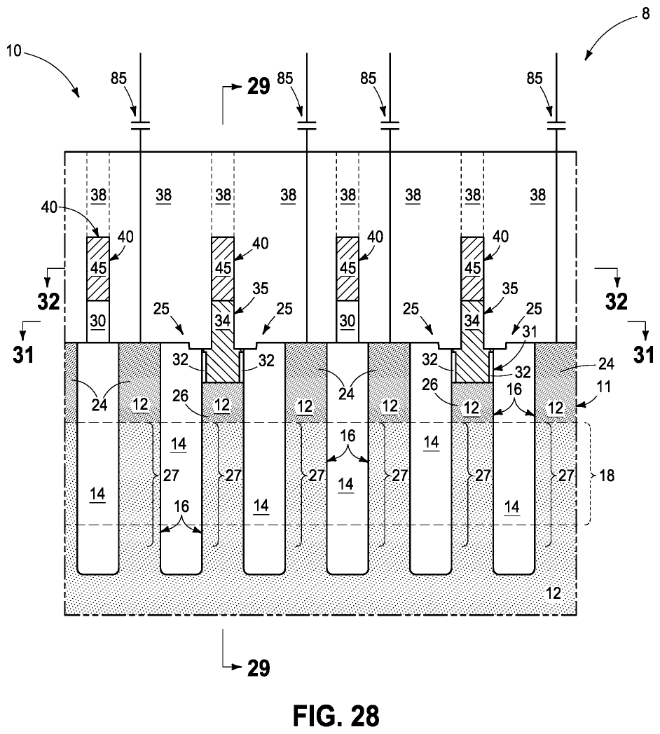

Referring to FIGS. 28-33, digitlines 40 have been formed directly above insulative material 30 and that are individually electrically coupled (e.g., ideally directly electrically coupled) to conductor material 34 of one of individual conductive-via constructions 35, for example along a line of a plurality of such constructions. Insulative material 38 (e.g., comprising silicon nitride and/or silicon dioxide) is shown as having been formed for interlevel electrical isolation (e.g., before and/or after forming digitlines 40). In one embodiment and as shown, the forming of digitlines 40 comprises forming conducting material 45 thereof directly above individual conductive-via constructions 35 over such and insulative material 30 (e.g., blanketly), followed by formation of insulative material 38 over conducting material 45. This is followed by etching through conducting material 45 (and insulative material 38 when present), through laterally-outer insulator material 32, and through laterally-inner insulator material 37 in forming digitlines 40. More insulative material 38 can than be deposited as shown to fill the gaps between immediately-adjacent digitlines 40. Regardless, in one embodiment and as shown, laterally-outer insulator material 32 and laterally-inner insulator material 37 of individual conductive-via constructions 35 are directly under and not laterally-outward of individual digitlines 40 in the finished-circuitry construction. Alternately, laterally-outer insulator material 32 and laterally-inner insulator material 37 may not be so etched in forming digitlines 40 whereby materials 32 and 37 may appear as shown in FIG. 27 in the finished-circuitry construction (not shown in the finished-circuitry construction).

FIGS. 28-33 also show storage elements 85 (e.g., capacitors) having been formed that are individually electrically coupled (e.g., ideally directly electrically coupled) to individual of the one source/drain regions 24.

In one embodiment, laterally-inner insulator material 37 in the finished-circuitry construction has a bottom 42 (FIG. 33) that is above a bottom 44 of insulative material 30 that is directly above transistors 25. In one such embodiment, laterally-outer insulator material 32 has a bottom 46 that is below bottom 42 of laterally-inner insulator material 37 and, in one such embodiment, bottom 46 of laterally-outer insulator material 32 is below bottom 44 of insulative material 30.

Any other attribute(s) or aspect(s) as shown and/or described herein with respect to other embodiments may be used in the embodiments shown and described with reference to the above embodiments.

In one embodiment, a method used in forming memory circuitry (e.g., 10) comprises forming transistors (e.g., 25) individually comprising one source/drain region (e.g., 24) and another source/drain region (e.g., 26). A channel region (e.g., 27) between the one and the another source/drain regions. A conductive gate (e.g., 22) is operatively proximate the channel region. Conductive-via constructions (e.g., 35) are formed and that are individually directly above individual of the another source/drain regions. Individual of the conductive-via constructions comprise a conductor material (e.g., 34) that is electrically coupled to one of the individual another source/drain regions. Such also comprise an insulator lining (e.g., 50) laterally-outward of the conductor material. The insulator lining comprises a laterally-outer insulator material (e.g., 32) and a laterally-inner insulator material (e.g., 37) having an interface (e.g., 79) there-between. Digitlines (e.g., 40) are formed and that are individually electrically coupled to the conductor material of one of the individual conductive-via constructions. Storage elements (e.g., 85) are formed and that are individually electrically coupled to individual of the one source/drain regions. Any other attribute(s) or aspect(s) as shown and/or described herein with respect to other embodiments may be used.

Method embodiments of the invention using an insulator lining comprising a laterally-outer insulator material and a laterally-inner insulator material having an interface there-between in the manner(s) described may reduce risk of conductor material 34 of conductive-via constructions 35 shorting with storage elements 85 and/or reduce degree of etching into another source/drain regions 26 when forming openings 31.

Alternate embodiment constructions may result from method embodiments described above, or otherwise. Regardless, embodiments of the invention encompass memory arrays independent of method of manufacture. Nevertheless, such memory arrays may have any of the attributes as described herein in method embodiments. Likewise, the above-described method embodiments may incorporate, form, and/or have any of the attributes described with respect to device embodiments.

In one embodiment, memory circuitry (e.g., 8) comprises transistors (e.g., 25) individually comprising one source/drain region (e.g., 24) and another source/drain region (e.g., 26). A channel region (e.g., 27) is between the one and the another source/drain regions. A conductive gate (e.g., 22) is operatively proximate the channel region. Conductive-via constructions 35 are individually directly above individual of the another source/drain regions. Individual of the conductive-via constructions comprise a conductor material (e.g., 34) that is electrically coupled to one of the individual another source/drain regions. The conductive-via constructions also comprise an insulator lining (e.g., 50) laterally-outward of the conductor material. The insulator lining comprises a laterally-outer insulator material (e.g., 32) and a laterally-inner insulator material (e.g., 37) having an interface (e.g., 79) there-between. Digitlines (e.g., 40) are individually directly electrically coupled to the conductor material of a plurality of the conductive-via constructions along a line of multiple of the transistors. Storage elements (e.g., 85) are individually electrically coupled to individual of the one source/drain regions. Any other attribute(s) or aspect(s) as shown and/or described herein with respect to other embodiments may be used.

The above processing(s) or construction(s) may be considered as being relative to an array of components formed as or within a single stack or single deck of such components above or as part of an underlying base substrate (albeit, the single stack/deck may have multiple tiers). Control and/or other peripheral circuitry for operating or accessing such components within an array may also be formed anywhere as part of the finished construction, and in some embodiments may be under the array (e.g., CMOS under-array). Regardless, one or more additional such stack(s)/deck(s) may be provided or fabricated above and/or below that shown in the figures or described above. Further, the array(s) of components may be the same or different relative one another in different stacks/decks and different stacks/decks may be of the same thickness or of different thicknesses relative one another. Intervening structure may be provided between immediately-vertically-adjacent stacks/decks (e.g., additional circuitry and/or dielectric layers). Also, different stacks/decks may be electrically coupled relative one another. The multiple stacks/decks may be fabricated separately and sequentially (e.g., one atop another), or two or more stacks/decks may be fabricated at essentially the same time.

The assemblies and structures discussed above may be used in integrated circuits/circuitry and may be incorporated into electronic systems. Such electronic systems may be used in, for example, memory modules, device drivers, power modules, communication modems, processor modules, and application-specific modules, and may include multilayer, multichip modules. The electronic systems may be any of a broad range of systems, such as, for example, cameras, wireless devices, displays, chip sets, set top boxes, games, lighting, vehicles, clocks, televisions, cell phones, personal computers, automobiles, industrial control systems, aircraft, etc.

In this document unless otherwise indicated, “elevational”, “higher”, “upper”, “lower”, “top”, “atop”, “bottom”, “above”, “below”, “under”, “beneath”, “up”, and “down” are generally with reference to the vertical direction. “Horizontal” refers to a general direction (i.e., within 10 degrees) along a primary substrate surface and may be relative to which the substrate is processed during fabrication, and vertical is a direction generally orthogonal thereto. Reference to “exactly horizontal” is the direction along the primary substrate surface (i.e., no degrees there-from) and may be relative to which the substrate is processed during fabrication. Further, “vertical” and “horizontal” as used herein are generally perpendicular directions relative one another and independent of orientation of the substrate in three-dimensional space. Additionally, “elevationally-extending” and “extend(ing) elevationally” refer to a direction that is angled away by at least 45° from exactly horizontal. Further, “extend(ing) elevationally”, “elevationally-extending”, “extend(ing) horizontally”, “horizontally-extending” and the like with respect to a field effect transistor are with reference to orientation of the transistor's channel length along which current flows in operation between the source/drain regions. For bipolar junction transistors, “extend(ing) elevationally” “elevationally-extending”, “extend(ing) horizontally”, “horizontally-extending” and the like, are with reference to orientation of the base length along which current flows in operation between the emitter and collector. In some embodiments, any component, feature, and/or region that extends elevationally extends vertically or within 10° of vertical.

Further, “directly above”, “directly below”, and “directly under” require at least some lateral overlap (i.e., horizontally) of two stated regions/materials/components relative one another. Also, use of “above” not preceded by “directly” only requires that some portion of the stated region/material/component that is above the other be elevationally outward of the other (i.e., independent of whether there is any lateral overlap of the two stated regions/materials/components). Analogously, use of “below” and “under” not preceded by “directly” only requires that some portion of the stated region/material/component that is below/under the other be elevationally inward of the other (i.e., independent of whether there is any lateral overlap of the two stated regions/materials/components).

Any of the materials, regions, and structures described herein may be homogenous or non-homogenous, and regardless may be continuous or discontinuous over any material which such overlie. Where one or more example composition(s) is/are provided for any material, that material may comprise, consist essentially of, or consist of such one or more composition(s). Further, unless otherwise stated, each material may be formed using any suitable existing or future-developed technique, with atomic layer deposition, chemical vapor deposition, physical vapor deposition, epitaxial growth, diffusion doping, and ion implanting being examples.

Additionally, “thickness” by itself (no preceding directional adjective) is defined as the mean straight-line distance through a given material or region perpendicularly from a closest surface of an immediately-adjacent material of different composition or of an immediately-adjacent region. Additionally, the various materials or regions described herein may be of substantially constant thickness or of variable thicknesses. If of variable thickness, thickness refers to average thickness unless otherwise indicated, and such material or region will have some minimum thickness and some maximum thickness due to the thickness being variable. As used herein, “different composition” only requires those portions of two stated materials or regions that may be directly against one another to be chemically and/or physically different, for example if such materials or regions are not homogenous. If the two stated materials or regions are not directly against one another, “different composition” only requires that those portions of the two stated materials or regions that are closest to one another be chemically and/or physically different if such materials or regions are not homogenous. In this document, a material, region, or structure is “directly against” another when there is at least some physical touching contact of the stated materials, regions, or structures relative one another. In contrast, “over”, “on”, “adjacent”, “along”, and “against” not preceded by “directly” encompass “directly against” as well as construction where intervening material(s), region(s), or structure(s) result(s) in no physical touching contact of the stated materials, regions, or structures relative one another.

Herein, regions-materials-components are “electrically coupled” relative one another if in normal operation electric current is capable of continuously flowing from one to the other and does so predominately by movement of subatomic positive and/or negative charges when such are sufficiently generated. Another electronic component may be between and electrically coupled to the regions-materials-components. In contrast, when regions-materials-components are referred to as being “directly electrically coupled”, no intervening electronic component (e.g., no diode, transistor, resistor, transducer, switch, fuse, etc.) is between the directly electrically coupled regions-materials-components.

Any use of “row” and “column” in this document is for convenience in distinguishing one series or orientation of features from another series or orientation of features and along which components have been or may be formed. “Row” and “column” are used synonymously with respect to any series of regions, components, and/or features independent of function. Regardless, the rows may be straight and/or curved and/or parallel and/or not parallel relative one another, as may be the columns. Further, the rows and columns may intersect relative one another at 90° or at one or more other angles (i.e., other than the straight angle).

The composition of any of the conductive/conductor/conducting materials herein may be conductive metal material and/or conductively-doped semiconductive/semiconductor/semiconducting material. “Metal material” is any one or combination of an elemental metal, any mixture or alloy of two or more elemental metals, and any one or more metallic compound(s).

Herein, any use of “selective” as to etch, etching, removing, removal, depositing, forming, and/or formation is such an act of one stated material relative to another stated material(s) so acted upon at a rate of at least 2:1 by volume. Further, any use of selectively depositing, selectively growing, or selectively forming is depositing, growing, or forming one material relative to another stated material or materials at a rate of at least 2:1 by volume for at least the first 75 Angstroms of depositing, growing, or forming.

Unless otherwise indicated, use of “or” herein encompasses either and both.

### CONCLUSION

In some embodiments, a method used in forming memory circuitry comprises forming transistors individually comprising one source/drain region and another source/drain region. A channel region is between the one and the another source/drain regions. A conductive gate is operatively proximate the channel region. Conductive-via constructions are formed that are individually directly above individual of the another source/drain regions. Individual of the conductive-via constructions comprise a conductor material that is electrically coupled to one of the individual another source/drain regions. An insulator lining is laterally-outward of the conductor material. The insulator lining comprises a laterally-outer insulator material and a laterally-inner insulator material that are directly against one another and have an interface there-between. Digitlines are formed that are individually electrically coupled to the conductor material of one of the individual conductive-via constructions. Storage elements are formed that are individually electrically coupled to individual of the one source/drain regions.

In some embodiments, a method used in forming memory circuitry comprises forming transistors individually comprising one source/drain region and another source/drain region. A channel region is between the one and the another source/drain regions. A conductive gate is operatively proximate the channel region. Openings are formed through insulative material that is directly above the transistors and into the another source/drain regions. Individual of the openings are directly above individual of the another source/drain regions. A laterally-outer insulator material is formed in the individual openings within and below the insulative material. A laterally-inner insulator material is formed in the individual openings within and below the insulative material laterally-over the laterally-outer insulator material. The laterally-outer insulator material and the laterally-inner insulator material are directly against one another and have an interface there-between. The laterally-inner insulator material that is in the individual openings below the insulative material is removed. After such removing, conductor material is formed in the individual openings that is electrically coupled to one of the individual another source/drain regions. The laterally-outer insulator material, the laterally-inner insulator material, and the conductor material that are in the individual openings comprise individual conductive-via constructions. Digitlines are formed directly above the insulative material and that are individually electrically coupled to the conductor material of one of the individual conductive-via constructions. Storage elements are formed that are individually electrically coupled to individual of the one source/drain regions.

In some embodiments, memory circuitry comprises transistors individually comprising one source/drain region and another source/drain region. A channel region is between the one and the another source/drain regions. A conductive gate is operatively proximate the channel region. Conductive-via constructions are individually directly above individual of the another source/drain regions. Individual of the conductive-via constructions comprise a conductor material that is electrically coupled to one of the individual another source/drain regions. An insulator lining is laterally-outward of the conductor material. The insulator lining comprises a laterally-outer insulator material and a laterally-inner insulator material that are directly against one another and have an interface there-between. Digitlines are individually directly electrically coupled to the conductor material of a plurality of the conductive-via constructions along a line of multiple of the transistors. Storage elements are individually electrically coupled to individual of the one source/drain regions.

In compliance with the statute, the subject matter disclosed herein has been described in language more or less specific as to structural and methodical features. It is to be understood, however, that the claims are not limited to the specific features shown and described, since the means herein disclosed comprise example embodiments. The claims are thus to be afforded full scope as literally worded, and to be appropriately interpreted in accordance with the doctrine of equivalents.

1. A method used in forming memory circuitry, comprising:
forming transistors individually comprising:
one source/drain region and another source/drain region;
a channel region between the one and the another source/drain regions; and
a conductive gate operatively proximate the channel region;
forming conductive-via constructions that are individually directly above individual of the another source/drain regions, individual of the conductive-via constructions comprising:
a conductor material that is electrically coupled to one of the individual another source/drain regions; and
an insulator lining laterally-outward of the conductor material, the insulator lining comprising a laterally-outer insulator material and a laterally-inner insulator material that are directly against one another and have an interface there-between;
forming digitlines that are individually electrically coupled to the conductor material of one of the individual conductive-via constructions; and
forming storage elements that are individually electrically coupled to individual of the one source/drain regions.

2. The method of claim 1 wherein the laterally-outer insulator material and the laterally-inner insulator material are of the same composition relative one another at the interface.

3. The method of claim 1 wherein the laterally-outer insulator material and the laterally-inner insulator material are of different compositions relative one another at the interface.

4. The method of claim 1 wherein the laterally-inner insulator material comprises a nitride.

5. The method of claim 4 wherein the nitride is doped with at least one of boron, phosphorus, and carbon.

6. The method of claim 4 wherein the nitride comprises at least one of boron nitride, silicon nitride, silicon oxynitride, and aluminum-poor aluminum nitride.

7. The method of claim 1 wherein the laterally-inner insulator material comprises an oxide.

8. The method of claim 7 wherein the oxide is doped with at least one of boron, phosphorus, and carbon.

9. The method of claim 7 wherein the oxide comprises at least one of silicon dioxide, germanium oxide, and an insulative metal oxide.

10. The method of claim 9 wherein the oxide comprises the insulative metal oxide and which comprises multiple different metals.

11. The method of claim 1 wherein the digitlines are individually directly electrically coupled to the conductor material of one of the individual conductive-via constructions.

12. The method of claim 1 wherein the storage elements are individually directly electrically coupled to the individual one source/drain regions.

13. The method of claim 1 wherein the laterally-inner insulator material in a finished-circuitry construction has a bottom that is above a bottom of insulative material that is directly above the transistors.

14. The method of claim 13 wherein the laterally-outer insulator material has a bottom that is below the bottom of the laterally-inner insulator material in the finished-circuitry construction.

15. The method of claim 14 wherein the bottom of the laterally-outer insulator material is below the bottom of the insulative material that is directly above the transistors in the finished-circuitry construction.

16. The method of claim 1 wherein forming the digitlines comprises:
forming conducting material of the digitlines directly above the individual conductive-via constructions; and
etching through the conducting material, through the laterally-outer insulator material, and through the laterally-inner insulator material in forming the digitlines.

17. The method of claim 1 wherein the laterally-outer insulator material and the laterally-inner insulator material of the individual conductive-via constructions are directly under and not laterally-outward of individual of the digitlines in a finished-circuitry construction.

18. A method used in forming memory circuitry, comprising:
forming transistors individually comprising:
one source/drain region and another source/drain region;
a channel region between the one and the another source/drain regions; and
a conductive gate operatively proximate the channel region;
forming openings through insulative material that is directly above the transistors and into the another source/drain regions, individual of the openings being directly above individual of the another source/drain regions;
forming a laterally-outer insulator material in the individual openings within and below the insulative material;
forming a laterally-inner insulator material in the individual openings within and below the insulative material laterally-over the laterally-outer insulator material, the laterally-outer insulator material and the laterally-inner insulator material being directly against one another and have an interface there-between;
removing the laterally-inner insulator material that is in the individual openings below the insulative material;
after the removing, forming conductor material in the individual openings that is electrically coupled to one of the individual another source/drain regions;
the laterally-outer insulator material, the laterally-inner insulator material, and the conductor material that are in the individual openings comprising individual conductive-via constructions;
forming digitlines directly above the insulative material and that are individually electrically coupled to the conductor material of one of the individual conductive-via constructions; and
forming storage elements that are individually electrically coupled to individual of the one source/drain regions.

19. The method of claim 18 wherein the removing of the laterally-inner insulator material removes all such material that is within the individual openings below the insulative material.

20. Memory circuitry, comprising:
transistors individually comprising:
one source/drain region and another source/drain region;
a channel region between the one and the another source/drain regions; and
a conductive gate operatively proximate the channel region;
conductive-via constructions that are individually directly above individual of the another source/drain regions, individual of the conductive-via constructions comprising:
a conductor material that is electrically coupled to one of the individual another source/drain regions; and
an insulator lining laterally-outward of the conductor material, the insulator lining comprising a laterally-outer insulator material and a laterally-inner insulator material that are directly against one another and have an interface there-between;
digitlines that are individually directly electrically coupled to the conductor material of a plurality of the conductive-via constructions along a line of multiple of the transistors; and
storage elements that are individually electrically coupled to individual of the one source/drain regions.
